(19) United States
(12) Patent Application Publication
(10) Pub. No.: US 2024/0113016 A1
(43) Pub. Date: Apr. 4, 2024

(54) SEMICONDUCTOR DEVICE

(71) Applicant: LAPIS SEMICONDUCTOR CO., LTD., Kanagawa (JP)

(72) Inventor: MANAMI KINASE, KANAGAWA (JP)

(21) Appl. No.: 18/371,554

(22) Filed: Sep. 22, 2023

(30) Foreign Application Priority Data
Sep. 30, 2022 (JP) 2022-159118

(51) Int. Cl. H01L 23/525; H01L 23/00

(52) U.S. Cl. CPC H01L 23/5256; H01L 24/05; H01L 24/13; H01L 2224/0218; H01L 2224/05551; H01L 2224/13018

(57) ABSTRACT

A semiconductor device, including: an insulating substrate provided with a substrate surface; a first conductive body and a second conductive body provided on the substrate surface; the second conductive body being separated from the first conductive body; an insulating film covering the first conductive body and the second conductive body; and a third conductive body provided on a face of the insulating film at an opposite side thereof from a side at which the substrate surface is disposed, the third conductive body penetrating the insulating film and contacting the second conductive body, wherein the insulating film includes a thinned portion at which a thickness of the insulating film is decreased such that the insulating film can be locally fractured by application of a voltage to the insulating film between the third conductive body and the first conductive body.

### CROSS-REFERENCE TO RELATED APPLICATION

This application is based on and claims priority under 35 USC 119 from Japanese Patent Application No. 2022-159118 filed on Sep. 30, 2022, the disclosure of which is incorporated by reference herein.

### BACKGROUND

### Technical Field

The present disclosure relates to a semiconductor device.

### Related Art

In a semiconductor device, a fuse is provided on an insulating substrate.

For example, Japanese Patent Application Laid-Open (JP-A) No. 2007-67087 recites a semiconductor device provided with a testing terminal region, a fuse region and a bump formation region. In a step for forming plated bumps, an etching protection film is formed on a fuse element portion of the fuse region and protects the fuse element portion from an etchant.

In the technology recited in JP-A No. 2007-67087, because the fuse is provided, the semiconductor device is provided with the fuse region separately from the bump formation region, which leads to an increase in size of the semiconductor device.

### SUMMARY

An object of the present disclosure is to reduce size of a semiconductor device provided with a fuse.

The present disclosure is a semiconductor device including: an insulating substrate provided with a substrate surface; a first conductive body provided on the substrate surface; a second conductive body provided on the substrate surface, the second conductive body being separated from the first conductive body; an insulating film provided at the substrate surface, the insulating film covering the first conductive body and the second conductive body; and a third conductive body provided on a face of the insulating film at an opposite side thereof from a side at which the substrate surface is disposed, the third conductive body penetrating the insulating film and contacting the second conductive body, wherein the insulating film includes a thinned portion at which a thickness of the insulating film, between a side thereof at which the third conductive body is disposed and a side at which the first conductive body is disposed, is decreased such that the insulating film can be locally fractured by application of a voltage to the insulating film between the third conductive body and the first conductive body.

According to the present disclosure, a semiconductor device provided with a fuse may be reduced in size.

### BRIEF DESCRIPTION OF THE DRAWINGS

Exemplary embodiments of the present disclosure will be described in detail based on the following figures, wherein:

FIG. 1 is a sectional diagram showing a semiconductor device according to a first exemplary embodiment;

FIG. 2 is a plan view showing the semiconductor device according to the first exemplary embodiment;

FIG. 3 is a sectional diagram showing the semiconductor device according to the first exemplary embodiment in a state in which a rupture has occurred;

FIG. 4 is a sectional diagram showing a semiconductor device according to a second exemplary embodiment;

FIG. 5 is a sectional diagram showing a semiconductor device according to a third exemplary embodiment;

FIG. 6 is a sectional diagram showing a semiconductor device according to a fourth exemplary embodiment;

FIG. 7 is a sectional diagram showing a semiconductor device according to a fifth exemplary embodiment;

FIG. 8 is a sectional diagram showing a semiconductor device according to a first variant example of the first exemplary embodiment; and

FIG. 9 is a sectional diagram showing a semiconductor device according to a second variant example of the first exemplary embodiment.

### DETAILED DESCRIPTION

A semiconductor device according to the present disclosure is described with reference to the drawings. For convenience of description, a width direction of the semiconductor device is indicated by arrow W in the drawings and a vertical direction is indicated by arrow U. Note that these directions do not limit actual states of use of the semiconductor device.

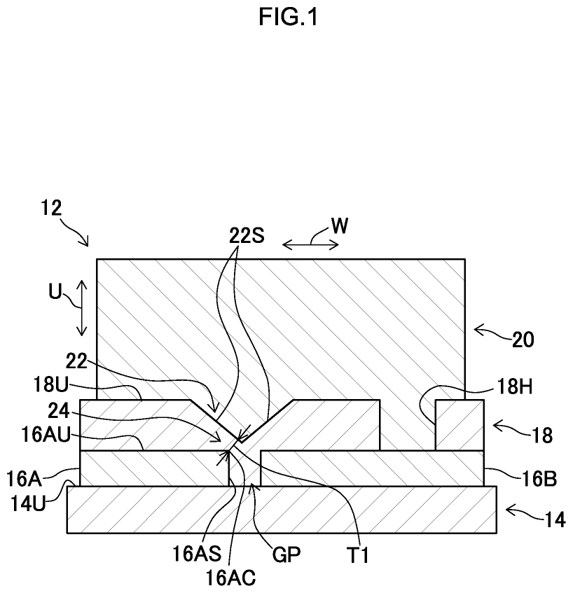

FIG. 1 depicts a semiconductor device 12 according to a first exemplary embodiment. The semiconductor device 12 includes a substrate 14, a first conductive body 16A, a second conductive body 16B, an insulating film 18 and a third conductive body 20.

The substrate 14 is formed of an insulating material. A surface at the upper side of the substrate 14 is a flat substrate surface 14U.

The first conductive body 16A and second conductive body 16B are provided on the substrate surface 14U. The first conductive body 16A and second conductive body 16B are both formed of a conductor such as copper or the like. The first conductive body 16A and second conductive body 16B are separated in an intra-surface direction of the substrate surface 14U. Thus, a predetermined gap GP is formed between the first conductive body 16A and the second conductive body 16B. The first conductive body 16A and second conductive body 16B structure the same layer on the substrate surface 14U. For example, when the structure of the semiconductor device 12 includes plural conductive layers, the first conductive body 16A and second conductive body 16B are in a layer structuring an uppermost layer.

The insulating film 18 is provided on the substrate surface 14U. The insulating film 18 is formed as a film so as to be continuous from a region of the substrate surface 14U in which the first conductive body 16A and second conductive body 16B are not provided (a region in which the gap GP is formed) to an upper face of the first conductive body 16A and an upper face of the second conductive body 16B.

The insulating film 18 is formed of an insulating material. The insulating film 18 covers the first conductive body 16A and second conductive body 16B at an opposite sides thereof from the substrate surface 14U. The insulating film 18 acts as a protective film for the first conductive body 16A and second conductive body 16B.

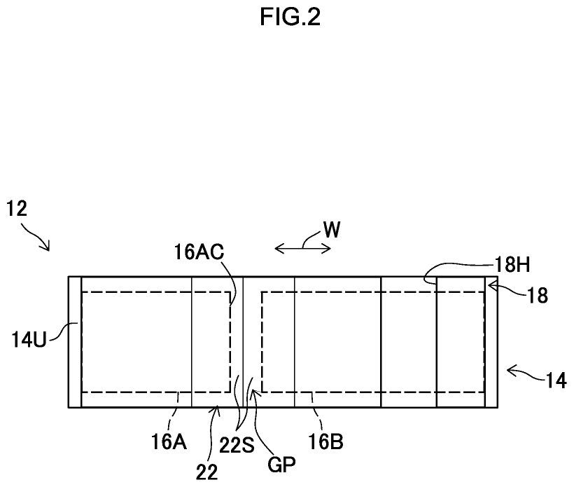

A penetrating hole 18H is formed in the insulating film 18. The penetrating hole 18H penetrates the insulating film 18 in the thickness direction thereof. As shown in FIG. 2 in a direction normal to the substrate surface 14U, the position of the penetrating hole 18H is a position that partially overlaps with the second conductive body 16B.

The third conductive body 20 is provided on an upper face 18U of the insulating film 18 (a face at the opposite side of the insulating film 18 from the substrate surface 14U). A portion of the third conductive body 20 is provided so as to enter into the penetrating hole 18H of the insulating film 18. Because a portion of the third conductive body 20 enters into the insulating film 18 and penetrates the insulating film 18, the third conductive body 20 is in contact with the second conductive body 16B. The third conductive body 20 is formed of a conductor. In the example illustrated in FIG. 1, the third conductive body 20 is a bump.

A recess portion 22 is formed in the insulating film 18, in the upper face 18U thereof. The recess portion 22 has a shape in which a portion of the upper face 18U of the insulating film 18 is recessed toward a side at which the substrate surface 14U is disposed. Because the recess portion 22 is formed, a region in which the thickness of the insulating film 18 is partially decreased (with a thickness T1 at a thinnest portion) is formed between the side of the insulating film 18 at which the third conductive body 20 is disposed and the side of the insulating film 18 at which the first conductive body 16A is disposed. A vicinity of a portion of the insulating film 18 at which the thickness is T1 is a thinned portion 24. As described below, the thinned portion 24 is a region in which the thickness is decreased such that the insulating film 18 can be locally fractured when a predetermined voltage is applied to the insulating film 18 between a side at which the third conductive body 20 is disposed and a side at which the first conductive body 16A is disposed. That is, the thinned portion 24 is a region of the semiconductor device 12 that forms a fuse. The thinned portion 24 is at a position that overlaps with the third conductive body 20 as viewed in the normal direction of the substrate surface 14U.

In the technology of the present disclosure, the fuse is a member or portion that changes from an insulating state to a conducting state when fractured by a certain condition (application of a voltage in the example mentioned above).

In the first exemplary embodiment, as viewed in the section of FIG. 1, the shape of the recess portion 22 is a triangular shape that is oriented downward. Side faces 22S of the recess portion 22 are inclined relative to the substrate surface 14U. Some of the recess portion 22 overlaps with the first conductive body 16A as viewed in the normal direction of the substrate surface 14U.

Therefore, in the first exemplary embodiment, the partial thinnest region of the insulating film 18 (the region with thickness T1) is formed, more specifically, between one of the side faces 22S of the recess portion 22 and a corner portion 16AC of the first conductive body 16A. The thinned portion 24 is a vicinity of this thinnest region. A portion of the thinned portion 24 overlaps with the first conductive body 16A as viewed in the normal direction of the substrate surface 14U. In the first exemplary embodiment, the thickness T1 of the thinnest portion of the insulating film 18 occurs in a direction that is inclined relative to the substrate surface 14U.

Now, operation of the first exemplary embodiment is described.

In the semiconductor device 12, the third conductive body 20 and second conductive body 16B conduct with one another, but the third conductive body 20 and first conductive body 16A are insulated from one another by the insulating film 18. The first conductive body 16A and second conductive body 16B are also insulated from one another by a portion of the insulating film 18 interposed between the first conductive body 16A and second conductive body 16B. Therefore, the first conductive body 16A and second conductive body 16B may be at different potentials. However, a situation in which the first conductive body 16A and second conductive body 16B should conduct with one another may arise, for example, in a fabrication process of the semiconductor device 12.

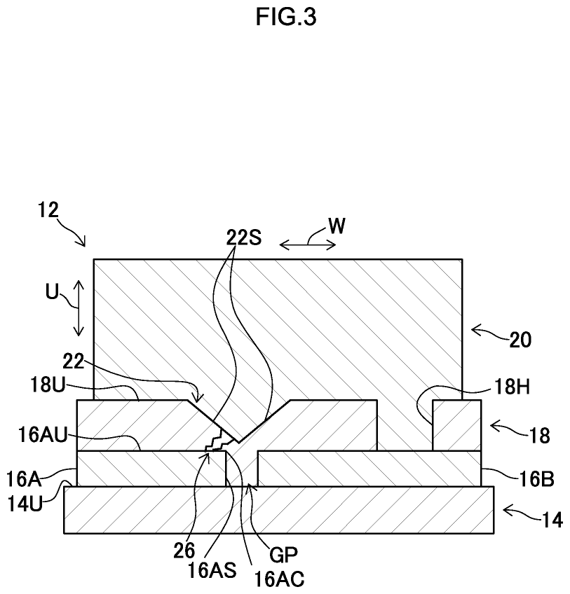

In the semiconductor device 12 according to the first exemplary embodiment, the thinned portion 24 is formed in the insulating film 18. At the thinned portion 24, the insulating film 18 is thinned so as to be locally fractured by application of a predetermined voltage to the insulating film 18, between the side at which the third conductive body 20 is disposed and the side at which the first conductive body 16A is disposed. In other words, the thinned portion 24 functions as a fuse. More specifically, when a voltage large enough to fracture the insulating film 18 at the thinned portion 24 is applied to the insulating film 18 between the third conductive body 20 and the first conductive body 16A, a rupture 26 is formed a the thinned portion 24 of the insulating film 18, as shown in FIG. 3. Through this rupture 26, the third conductive body 20 and the first conductive body 16A can conduct with one another.

In the semiconductor device 12 according to the first exemplary embodiment, a portion of the thinned portion 24 of the insulating film 18 is at a position that overlaps with the first conductive body 16A in the normal direction of the substrate surface 14U. That is, the thinned portion 24 is at positions of the first conductive body 16A or the gap GP in the width direction of the semiconductor device 12. The region in which the fuse is formed is not provided at a site in the width direction of the semiconductor device 12 that is different from the positions of all of the first conductive body 16A, the second conductive body 16B and the gap GP. Therefore, the semiconductor device 12 does not increase in size in the width direction, and a surface area of the semiconductor device 12 as viewed in the normal direction of the substrate surface 14U may be reduced.

If, for example, a laser were used to rupture a portion of the insulating film 18, tight collimation on a rupture location would be difficult. Therefore, a laser illumination range (a pitch between fuses) would have to be specified in advance to be a fairly wide laser illumination range (for example, a width of around 10 μm). In the present exemplary embodiment, because a laser is not used for forming the recess portion 22, there is no need to specify this wide laser illumination range, which may also contribute to a reduction in size of the semiconductor device 12.

In the semiconductor device 12 according to the first exemplary embodiment, the region in which the fuse is formed does not need to be provided at a different position from the third conductive body 20 (which is a bump in the example described above). That is, a layer structure forming the semiconductor device 12 is a structure including the substrate 14, the first conductive body 16A, the second conductive body 16B, the insulating film 18 and the third conductive body 20. Thus, the layer structure may resemble a layer structure of a semiconductor device in which the thinned portion 24 is not provided. Therefore, an increase in number of fabrication steps of the semiconductor device 12 may be suppressed.

Now, exemplary embodiments of the semiconductor device of the present disclosure that are different from the first exemplary embodiment described above are described. In the exemplary embodiments described below, the same reference symbols are assigned to elements, members and so forth that are the same, and detailed descriptions thereof are not given.

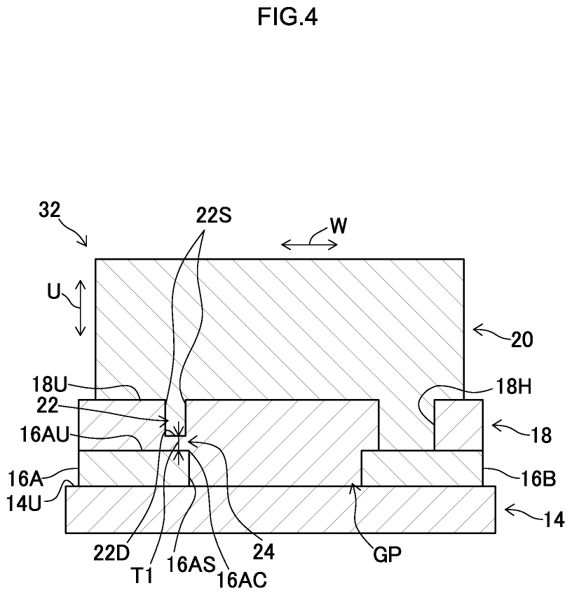

FIG. 4 shows a semiconductor device 32 according to a second exemplary embodiment. In the second exemplary embodiment, the shape of the recess portion 22 is a rectangular shape that is oriented downward as viewed in the section of FIG. 4. The side faces 22S of the recess portion 22 are perpendicular to the substrate surface 14U. When viewed in the normal direction of the substrate surface 14U, the whole of the recess portion 22 overlaps with the first conductive body 16A. In this second exemplary embodiment, the thinned portion 24 is formed between a floor face 22D of the recess portion 22 and an upper face 16AU of the first conductive body 16A. The whole of the thinned portion 24 is at a position overlapping with the first conductive body 16A. In the second exemplary embodiment, the thickness T1 of the thinnest portion of the insulating film 18 occurs in the direction perpendicular to the substrate surface 14U (the normal direction of the substrate surface 14U).

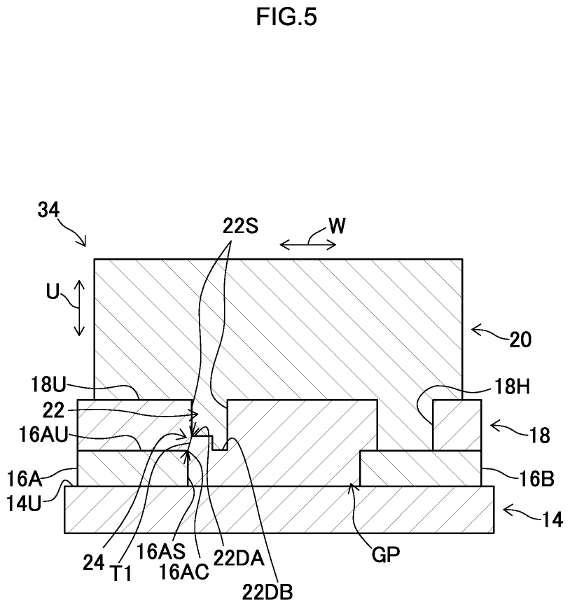

FIG. 5 shows a semiconductor device 34 according to a third exemplary embodiment. In the third exemplary embodiment, side faces of the recess portion 22 are perpendicular to the substrate surface 14U, and a bottom face region of the recess portion 22 includes a first floor face 22DA and a second floor face 22DB. The first floor face 22DA is at a relatively high position (a position further from the substrate surface 14U) and the second floor face 22DB is at a lower position (a position closer to the substrate surface 14U). When viewed in the normal direction of the substrate surface 14U, the whole of the thinned portion 24 is at a position between the first conductive body 16A and the second conductive body 16B. In this third exemplary embodiment, the first floor face 22DA is at a position closer to the first conductive body 16A than the second floor face 22DB, and the thinned portion 24 is formed between the first floor face 22DA and the upper face 16AU or corner portion 16AC of the first conductive body 16A. In the third exemplary embodiment, the thickness T1 of the thinnest portion of the insulating film 18 occurs in a direction that is inclined relative to the substrate surface 14U.

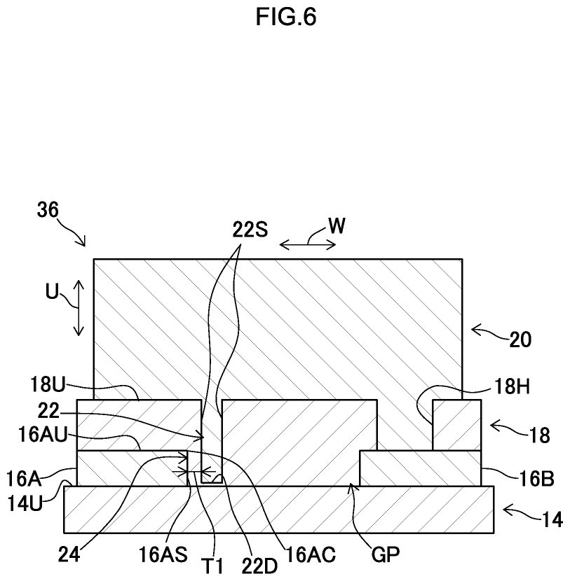

FIG. 6 shows a semiconductor device 36 according to a fourth exemplary embodiment. In the fourth exemplary embodiment, the shape of the recess portion 22 is a rectangular shape that is oriented downward as viewed in the section of FIG. 6. The side faces 22S of the recess portion 22 are perpendicular to the substrate surface 14U. When viewed in the normal direction of the substrate surface 14U (the vertical direction), the whole of the thinned portion 24 is between the first conductive body 16A and the second conductive body 16B. In this fourth exemplary embodiment, the recess portion 22 is formed (in the gap GP) to between the side faces 22S of the recess portion 22 and a side face 16AS of the first conductive body 16A. Thus, the thinned portion 24 is at a position of the gap GP. In the fourth exemplary embodiment, the thickness T1 of the thinnest portion of the insulating film 18 occurs in a direction parallel to the substrate surface 14U.

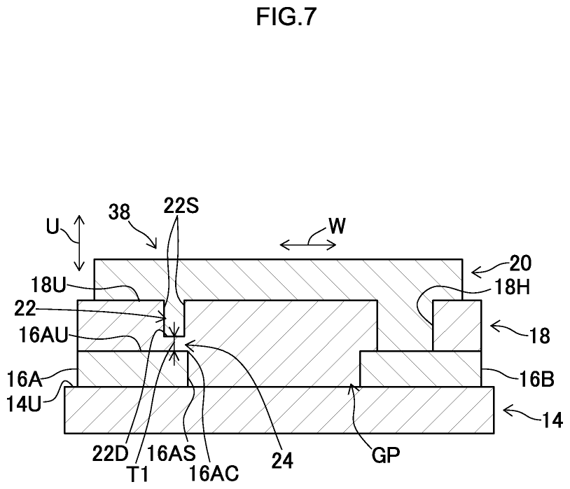

FIG. 7 shows a semiconductor device 38 according to a fifth exemplary embodiment. In the first to fourth exemplary embodiments described above, the third conductive body 20 is a bump, but in the fifth exemplary embodiment the shape of the third conductive body 20 differs from the third conductive body 20 according to the first to fourth exemplary embodiments, being a layer structure. Accordingly, in this fifth exemplary embodiment the third conductive body 20 constitutes an uppermost layer among conductive layers of the semiconductor device 12. The insulating film 18 may be an interlayer film provided between the conductive layer including the first conductive body 16A and second conductive body 16B and a conductive layer including the third conductive body 20. The penetrating hole 18H is a “via hole” formed in this interlayer film.

In the example shown in FIG. 7, an example is illustrated in which the shape of the recess portion 22 according to the fifth exemplary embodiment is a rectangular shape that is oriented downward, similarly to the second exemplary embodiment. However, the shape of this recess portion 22 may be, for example, a similar shape to any of the first, third and fourth exemplary embodiments.

In the fifth exemplary embodiment, a structure is possible in which a further insulating film and a bump are layered above the third conductive body 20.

In any of the second to fifth exemplary embodiments, the rupture 26 (see FIG. 3 illustrating the first exemplary embodiment) is formed by the application of a voltage to the insulating film 18 between the third conductive body 20 and the first conductive body 16A, enabling the third conductive body 20 and first conductive body 16A to conduct with one another. The region in which the fuse is formed is not provided at a position in the width direction of the semiconductor device 12 that is different from the sites of all of the first conductive body 16A, the second conductive body 16B and the gap GP. Therefore, the semiconductor device 12 does not increase in size in the width direction, and a surface area of the semiconductor device 12 as viewed in the normal direction of the substrate surface 14U may be reduced.

In any of the second to fifth exemplary embodiments, the layer structure forming the semiconductor device 12 may resemble a layer structure of a semiconductor device in which the thinned portion 24 is not provided. Therefore, an increase in number of fabrication steps of the semiconductor device 12 may be suppressed.

In the technology of the present disclosure, with regard to voltages applied between the first conductive body 16A and the third conductive body 20, a thickness of the insulating film 18 in a region of the thinned portion 24 may be set to a thickness at which the insulating film 18 is ruptured by a predetermined voltage. For example, when the insulating film 18 is a nitride film, the thickness of the thinned portion 24 has a a broadly proportional relationship with withstand voltage. To give a concrete example, if the thickness T1 of the thinnest portion of the insulating film 18 is 0.05 μm, the withstand voltage is around 50 V. In this example, if the thickness T1 is set to, for example, at most 0.08 μm, the thinned portion 24 may be ruptured without an applied voltage becoming excessively high, and if the thickness T1 is set to at least 0.02 μm, cases of the thinned portion 24 being excessively thin may be suppressed.

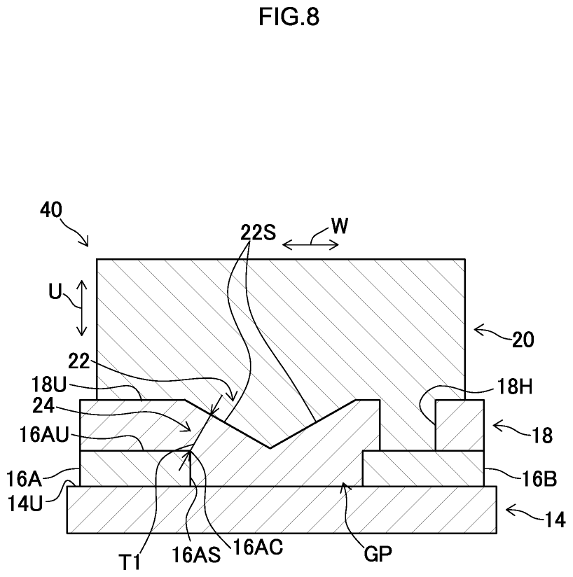

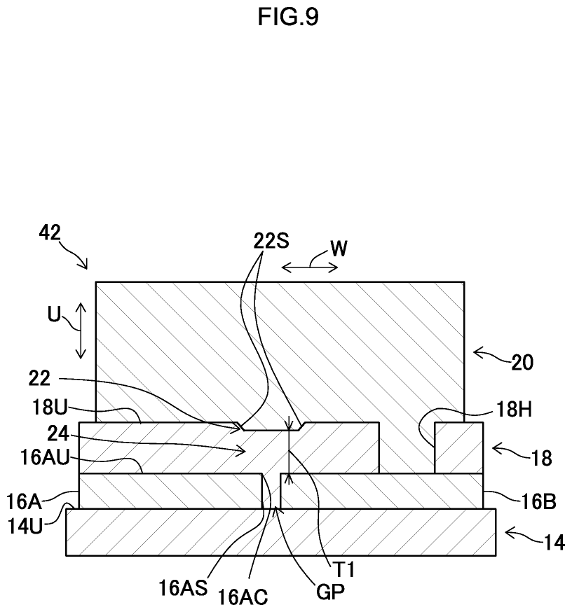

In the technology of the present disclosure, a method for forming the insulating film 18 is not particularly limited, but a chemical vapor deposition (CVD) method may be used. With chemical vapor deposition, when the gap GP between the first conductive body 16A and the second conductive body 16B is wider (for example, around 3 μm) as in a semiconductor device 40 according to a first variant example shown in FIG. 8, the thickness of the insulating film 18 at the thinned portion 24, particularly the thickness T1 of the thinnest portion, is thicker. When the gap GP between the first conductive body 16A and the second conductive body 16B is narrower (for example, around 0.4 μm) as in a semiconductor device 42 according to a second variant example shown in FIG. 9, the recess portion 22 is not formed to be deep and the thickness of the insulating film 18 at the thinned portion 24 (the thickness T1 of the thinnest portion) is again thicker. Therefore, it is appropriate to consider a relationship between the thickness of the insulating film 18 at the thinned portion 24 and the gap GP between the first conductive body 16A and second conductive body 16B, and adjust conditions of formation of the insulating film 18 such that a desired thickness is obtained.

The recess portion 22 may be formed by etching after the insulating film 18 has been formed with a constant thickness. For example, in the second to fifth exemplary embodiments, the side faces 22S of the recess portion 22 are perpendicular to the substrate surface 14U and formation of the recess portion 22 by etching is simple. When the recess portion 22 is formed by etching, adjustment of the position of the recess portion 22 is simple. For example, in the fourth exemplary embodiment as shown in FIG. 6, because the thickness T1 of the thinnest portion of the insulating film 18 occurs in the direction parallel to the substrate surface 14U, forming the recess portion 22 at a suitable position in the direction parallel to the substrate surface 14U is desirable. With etching, because the recess portion 22 is formed at a desired position, setting the thinned portion 24 to an appropriate thickness is simple.

The following supplementary notes are also disclosed.

—Supplementary Note 1—

A semiconductor device, includes:
an insulating substrate provided with a substrate surface;
a first conductive body provided on the substrate surface;
a second conductive body provided on the substrate surface, the second conductive body being separated from the first conductive body;
an insulating film provided at the substrate surface, the insulating film covering the first conductive body and the second conductive body; and
a third conductive body provided on a face of the insulating film at an opposite side thereof from a side at which the substrate surface is disposed, the third conductive body penetrating the insulating film and contacting the second conductive body.
wherein the insulating film includes a thinned portion at which a thickness of the insulating film, between a side thereof at which the third conductive body is disposed and a side at which the first conductive body is disposed, is decreased such that the insulating film can be locally fractured by application of a voltage to the insulating film between the third conductive body and the first conductive body.

—Supplementary Note 2—

In the semiconductor device according to supplementary note 1, a recess portion is formed at a portion of the face of the insulating film at the side thereof at which the third conductive body is disposed, the recess portion being recessed toward the side at which the substrate surface is disposed, and the thinned portion of the insulating film being formed by the recess portion.

—Supplementary Note 3—

In the semiconductor device according to supplementary note 2, a side face of the recess portion is inclined relative to the substrate surface.

—Supplementary Note 4—

In the semiconductor device according to supplementary note 2, a side face of the recess portion is perpendicular to the substrate surface.

—Supplementary Note 5—

In the semiconductor device according to any of supplementary notes 2 to 4, when viewed in a normal direction of the substrate surface, some or all of the recess portion is at a position overlapping with the first conductive body.

—Supplementary Note 6—

In the semiconductor device according to any of supplementary notes 2 to 4, when viewed in a normal direction of the substrate surface, the recess portion is at a position between the first conductive body and the second conductive body.

What is claimed is:

1. A semiconductor device, comprising:
an insulating substrate provided with a substrate surface;
a first conductive body provided on the substrate surface;
a second conductive body provided on the substrate surface, the second conductive body being separated from the first conductive body;
an insulating film provided at the substrate surface, the insulating film covering the first conductive body and the second conductive body; and
a third conductive body provided on a face of the insulating film at an opposite side thereof from a side at which the substrate surface is disposed, the third conductive body penetrating the insulating film and contacting the second conductive body,
wherein the insulating film includes a thinned portion at which a thickness of the insulating film, between a side thereof at which the third conductive body is disposed and a side at which the first conductive body is disposed, is decreased such that the insulating film can be locally fractured by application of a voltage to the insulating film between the third conductive body and the first conductive body.

2. The semiconductor device according to claim 1, wherein a recess portion is formed at a portion of the face of the insulating film at the side thereof at which the third conductive body is disposed, the recess portion being recessed toward a side at which the substrate surface is disposed, and the thinned portion of the insulating film being formed by the recess portion.

3. The semiconductor device according to claim 2, wherein a side face of the recess portion is inclined relative to the substrate surface.

4. The semiconductor device according to claim 2, wherein a side face of the recess portion is perpendicular to the substrate surface.

5. The semiconductor device according to claim 2 wherein, when viewed in a normal direction of the substrate surface, some or all of the recess portion is at a position overlapping with the first conductive body.

6. The semiconductor device according to claim 2, wherein, when viewed in a normal direction of the substrate surface, the recess portion is at a position between the first conductive body and the second conductive body.
